(19) United States
(12) Patent Application Publication
(10) Pub. No.: US 2018/0061660 A1
(43) Pub. Date: Mar. 1, 2018

(54) Barrier Layer Formation Using Thermal Processing

(71) Applicant: Infineon Technologies AG, Neubiberg (DE)

(72) Inventors: Ravi Keshav Joshi, Villach (AT); Kae-Horng Wang, Villach (AT); Stefan Willkofer, Muenchen (DE)

(21) Appl. No.: 15/249,067

(22) Filed: Aug. 26, 2016

(51) Int. Cl. H01L 21/324; H01L 29/739; H01L 29/66; H01L 21/3213

(52) U.S. Cl. CPC H01L 21/324; H01L 21/32134; H01L 29/66348; H01L 29/7397

(57) ABSTRACT

A method of fabricating a semiconductor device includes forming a barrier layer over a surface of a semiconductor substrate. A treated barrier layer is formed by subjecting an exposed surface of the barrier layer to a surface treatment process. The surface treatment process includes treating the surface with a reactive material. A material layer is formed over the treated barrier layer. The material layer comprises a metal.

### TECHNICAL FIELD

The present invention relates generally to semiconductor processes, and, in particular embodiments, to methods of forming barrier layers using thermal processing.

### BACKGROUND

Semiconductor devices are used in many electronic and other applications. Semiconductor devices may comprise integrated circuits that are formed on semiconductor wafers. Alternatively, semiconductor devices may be formed as monolithic devices, e.g., discrete devices. Semiconductor devices are formed on semiconductor wafers by depositing many types of thin films of materials over the semiconductor wafers, patterning the thin films of material, doping selective regions of the semiconductor wafers, and other processes.

Reliability and product yield during manufacturing are important considerations for semiconductor devices. Diffusion of species between layers can cause device failures due to the formation of undesirable compounds and voids within the material layers. If the failure occurs during manufacturing, the resulting product may not pass performance qualifications during initial testing. Or worse they may be used in components that are eventually returned back due to failure. Barrier layers are used to prevent the passage of material between layers. In this capacity, barrier layers may improve device reliability, extend device lifetime, and increase the safe operating window of the device. However, as semiconductor devices with increased performance or smaller dimensions are fabricated, previously used barrier layers need to be improved.

### SUMMARY

In accordance with an embodiment of the present invention, a method of fabricating a semiconductor device includes forming a barrier layer over a surface of a semiconductor substrate. A treated barrier layer is formed by subjecting an exposed surface of the barrier layer to a surface treatment process. The surface treatment process includes treating the surface with a reactive material. A material layer is formed over the treated barrier layer. The material layer comprises a metal.

In accordance with an embodiment of the present invention, a method of fabricating a semiconductor device includes forming a metal silicide at a major surface of a semiconductor substrate. The method may also include forming a first conductive layer having a compressive stress over the metal silicide. The first conductive layer comprises a first metal, a second metal, and a reactive element that comprises nitrogen, boron, or carbon. The method may also include depositing a second conductive layer having a tensile stress, the second conductive layer contacting the first conductive layer.

In accordance with an embodiment of the present invention, a method of fabricating a semiconductor device includes forming a metal silicide at a major surface of a semiconductor substrate. The method may also include forming a first conductive layer having a compressive stress over the metal silicide. The first conductive layer comprises a first metal, a second metal, and a reactive element that comprises nitrogen, boron, or carbon. The method may also include depositing a second conductive layer having a tensile stress, the second conductive layer contacting the first conductive layer.

In accordance with another embodiment of the present invention, a semiconductor device includes a well region disposed at a first side of a semiconductor substrate. A doped region is disposed in the well region. A treated barrier layer is disposed over the doped region, the well region, and the first side of the semiconductor substrate. The treated barrier layer includes a reactive material and at least two metals. A top contact is disposed over the treated barrier layer. The top contact includes a metal different from the at least two metals.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1E illustrate a method of forming a treated barrier layer using thermal processing in accordance with an embodiment of the present invention,

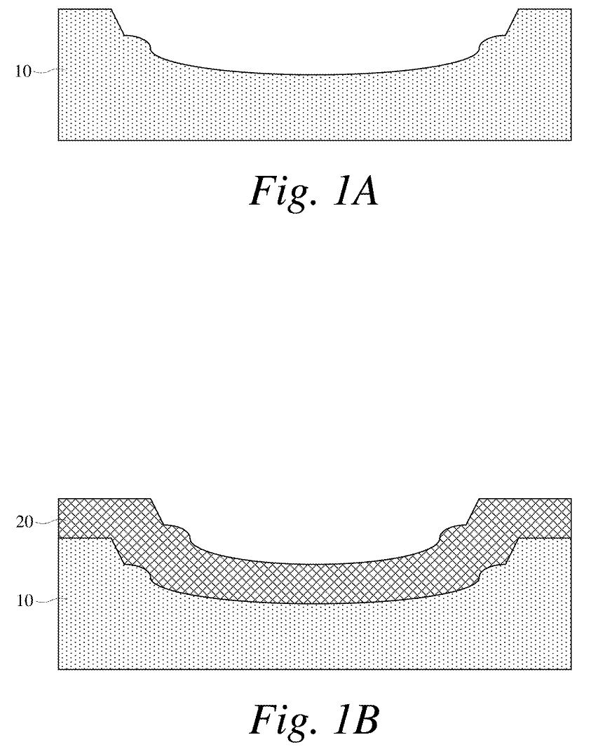

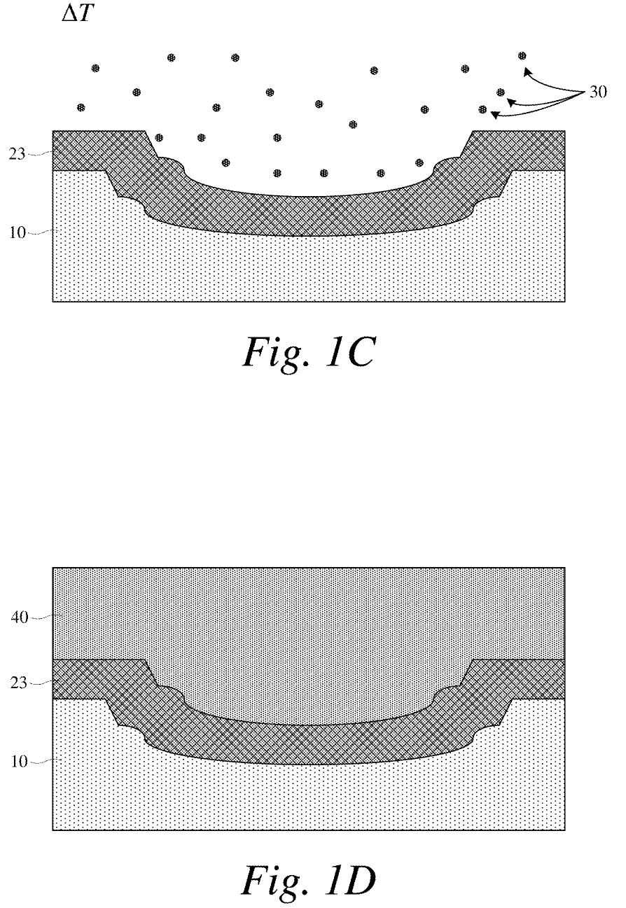

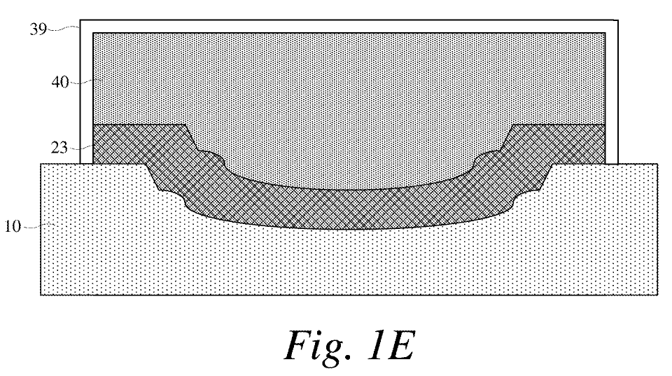

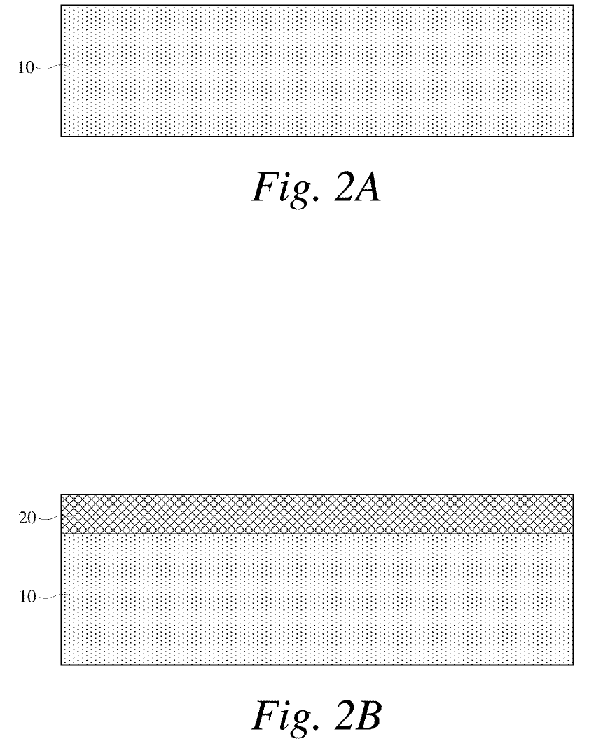

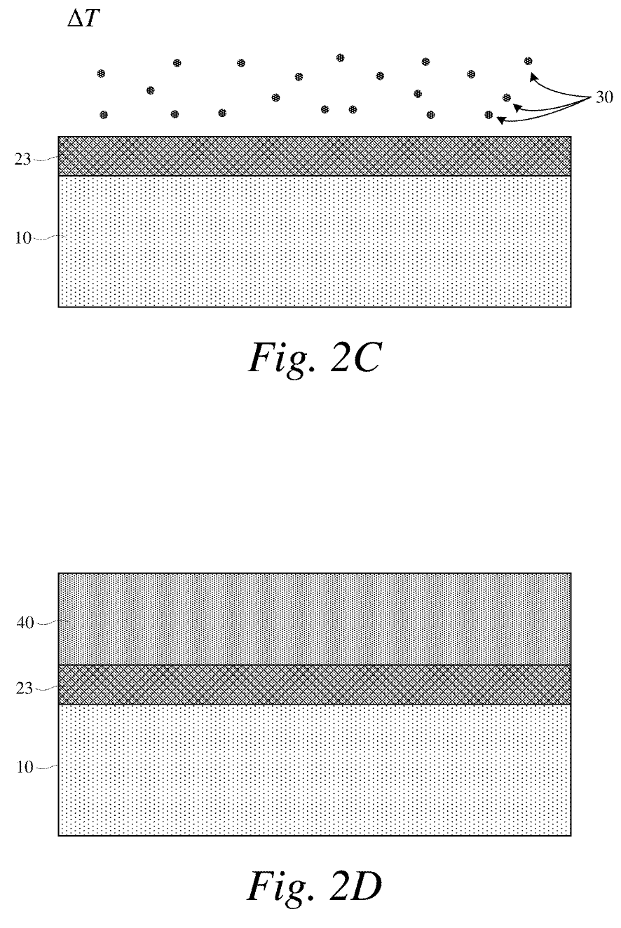

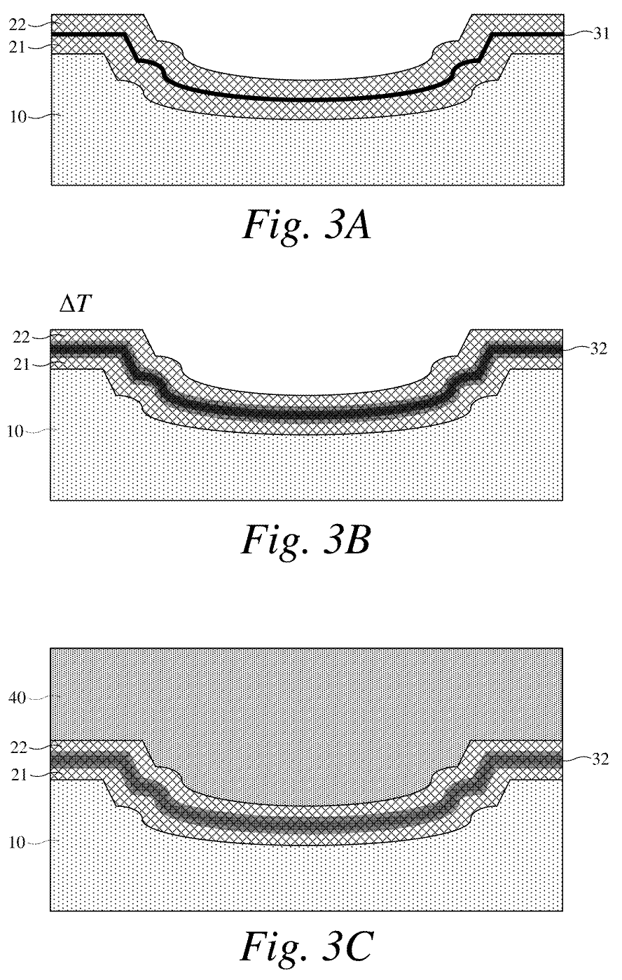

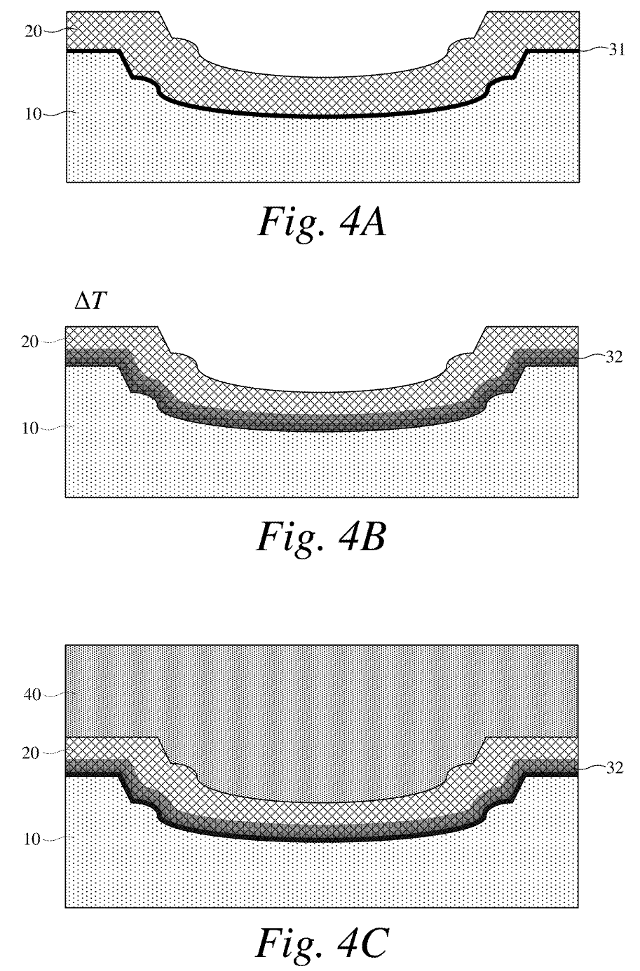

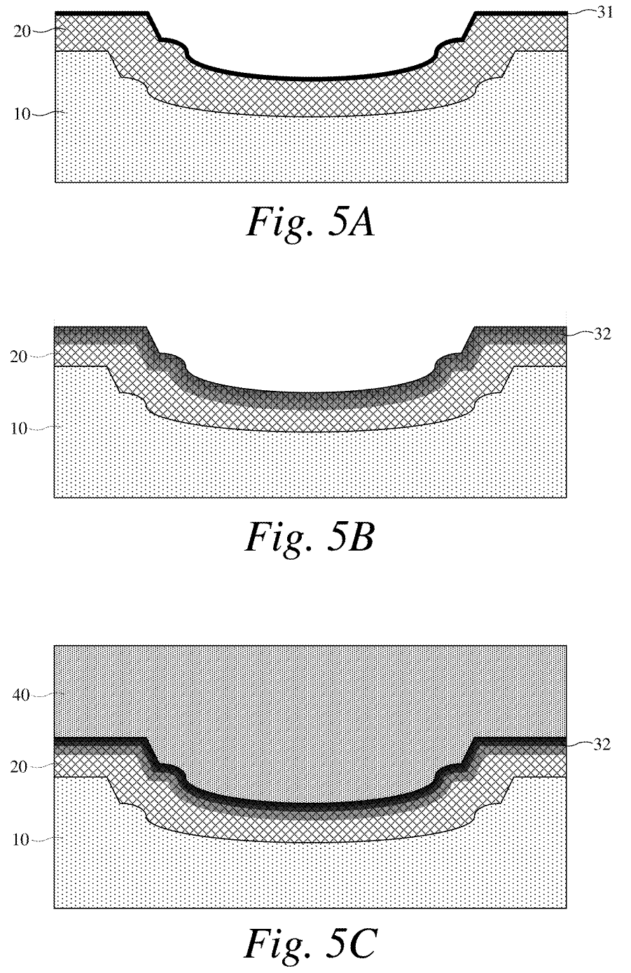

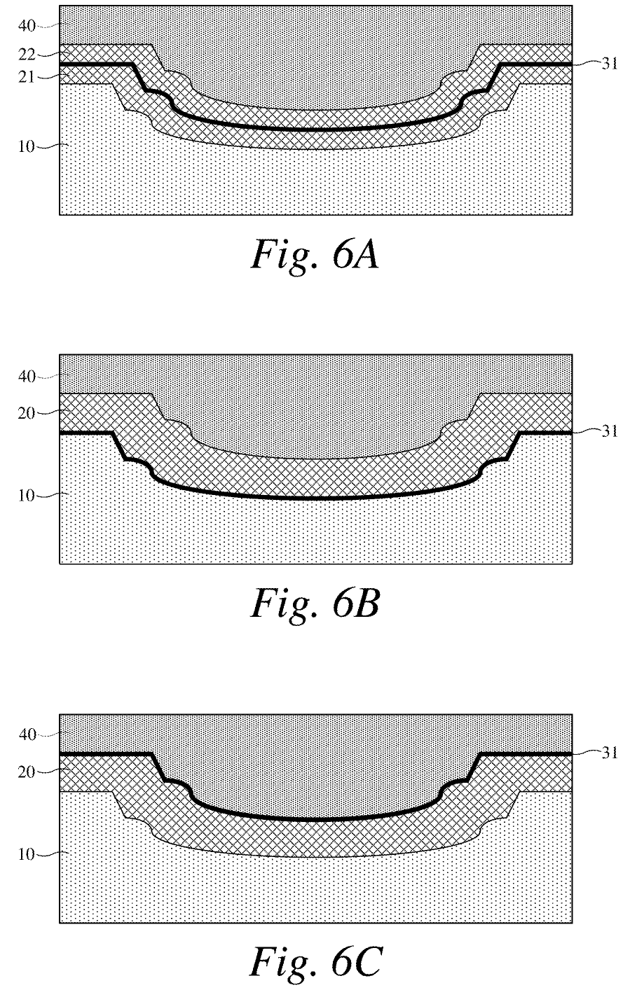

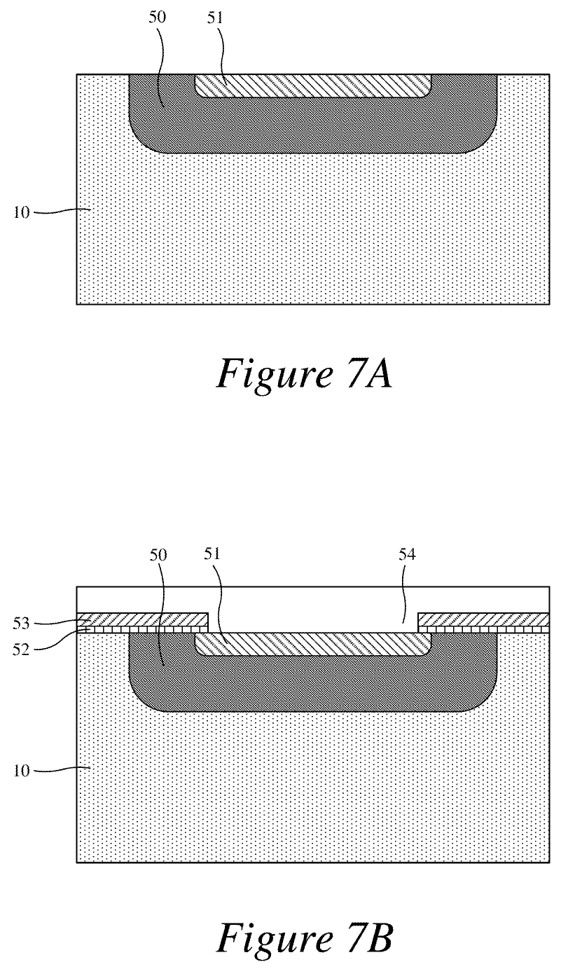

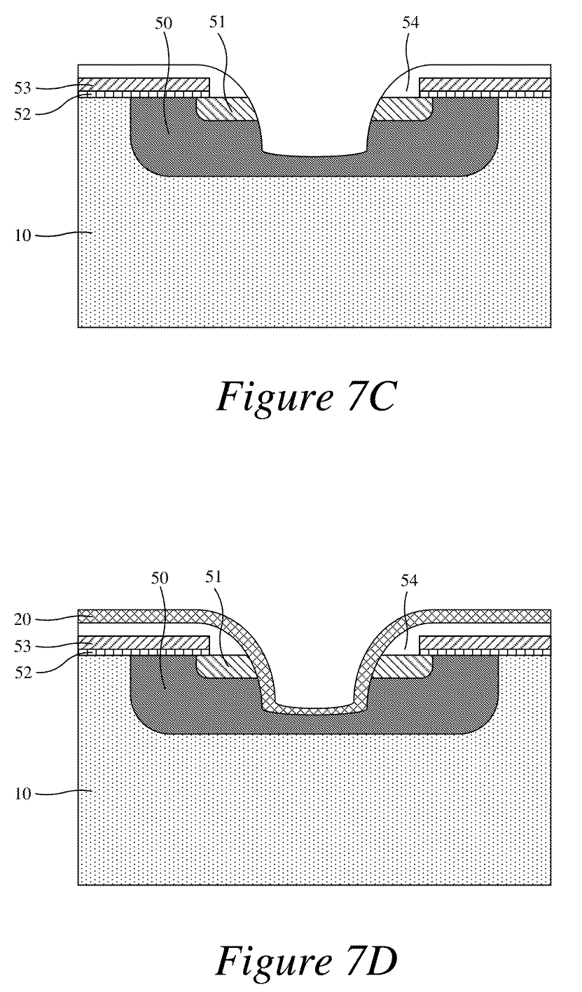

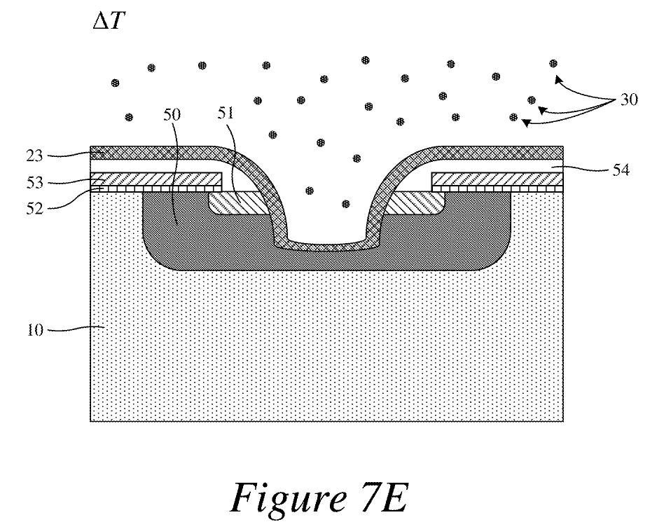

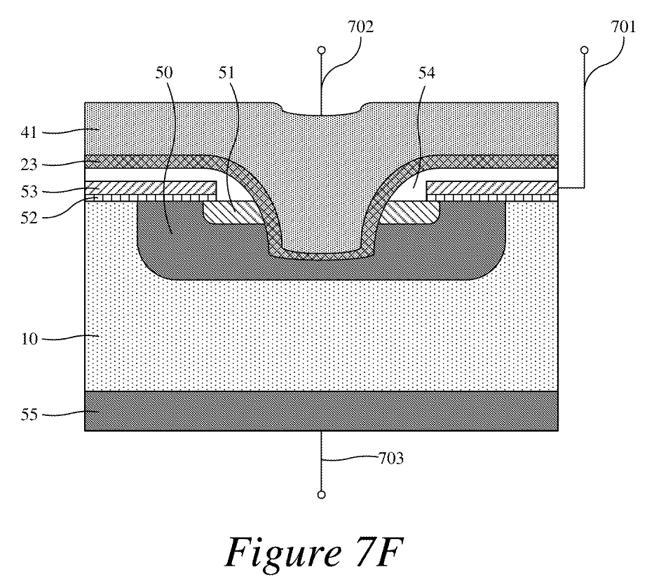

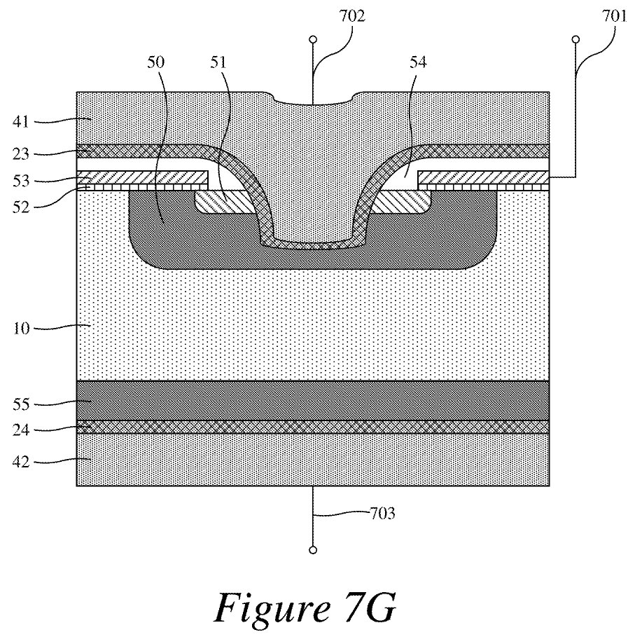

wherein FIG. 1A illustrates a cross-sectional view of a substrate after forming a recessed region,

wherein FIG. 1B illustrates a cross-sectional view of the substrate after forming a barrier layer over the surface of the substrate and the recessed region,

wherein FIG. 1C illustrates a cross-sectional view of the substrate during formation of a treated barrier layer using a thermal processing step in the presence of a reactive material,

wherein FIG. 1D illustrates a cross-sectional view of the substrate after forming a material layer over the treated barrier layer.

wherein FIG. 1E illustrates a cross-sectional view of the substrate after removing portions of the material layer and the treated barrier layer using a wet etching process;

FIGS. 2A-2D illustrate a method of forming a treated barrier layer using thermal processing in accordance with an alternative embodiment of the present invention,

wherein FIG. 2A illustrates a cross-sectional view of a substrate,

wherein FIG. 2B illustrates a cross-sectional view of the substrate after forming a barrier layer over the surface of the substrate,

wherein FIG. 2C illustrates a cross-sectional view of the substrate during formation of a treated barrier layer using a thermal processing step in the presence of a reactive material, and

wherein FIG. 2D illustrates a cross-sectional view of the substrate after forming a material layer over the treated barrier layer;

FIGS. 3A-3C illustrate a method of forming a barrier layer using thermal processing in accordance with another alternative embodiment of the present invention,

wherein FIG. 3A illustrates a cross-sectional view of a substrate after forming a first barrier layer, a barrier modifier material source layer, and a second barrier layer over the surface of the substrate,

wherein FIG. 3B illustrates a cross-sectional view of the substrate after forming a mixed region using a thermal processing step, and

wherein FIG. 3C illustrates a cross-sectional view of the substrate after forming a material layer over the second barrier layer;

FIGS. 4A-4C illustrate a method of forming a barrier layer using thermal processing in accordance with still another alternative embodiment of the present invention,

wherein FIG. 4A illustrates a cross-sectional view of a substrate after forming a barrier modifier material source layer and then a barrier layer over the surface of a substrate,

wherein FIG. 4B illustrates a cross-sectional view of the substrate after forming a mixed region using a thermal processing step, and

wherein FIG. 4C illustrates a cross-sectional view of the substrate after forming a material layer over the barrier layer;

FIGS. 5A-5C illustrate a method of forming a barrier layer using thermal processing in accordance with yet another alternative embodiment of the present invention,

wherein FIG. 5A illustrates a cross-sectional view of a substrate after forming a barrier layer and then a barrier modifier material source layer over the surface of a substrate,

wherein FIG. 5B illustrates a cross-sectional view of the substrate after forming a mixed region using a thermal processing step, and

wherein FIG. 5C illustrates a cross-sectional view of the substrate after forming a material layer over the mixed region;

FIGS. 6A-6C illustrate a method of forming a barrier layer in accordance with an embodiment of the present invention,

wherein FIG. 6A illustrates a cross-sectional view of a substrate after forming a first barrier layer, a barrier modifier material source layer, a second barrier layer, and a material layer over the surface of the substrate,

wherein FIG. 6B illustrates a cross-sectional view of the substrate after forming a barrier modifier material source layer, a barrier layer, and a material layer over the surface of the substrate, and

wherein FIG. 6C illustrates a cross-sectional view of the substrate after forming a barrier layer, a barrier modifier material source layer, and a material layer over the surface of the substrate; and

FIGS. 7A-7G illustrate a method of forming a semiconductor device comprising a treated barrier layer in accordance with an embodiment of the present invention,

wherein FIG. 7A illustrates a cross-sectional view of a substrate after forming a deep well region in the substrate and forming a well region within the deep well region,

FIG. 7B illustrates a cross-sectional view of the substrate after forming a gate dielectric, forming a gate material over the gate dielectric, and forming an insulating region over the gate material,

wherein FIG. 7C illustrates a cross-sectional view of the substrate after forming a recessed region in the insulating region, well region, and deep well region,

wherein FIG. 7D illustrates a cross-sectional view of the substrate after forming a barrier layer over the recessed region and the insulating region,

wherein FIG. 7E illustrates a cross-sectional view of the substrate during formation of a treated barrier layer using a thermal processing step in the presence of a reactive material,

wherein FIG. 7F illustrates a cross-sectional view of the substrate after forming a top contact over the treated barrier layer, and

wherein FIG. 7G illustrates a cross-sectional view of the substrate after adding a backside treated barrier layer and a backside contact.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

In conventional semiconductor processing, a silicon substrate is often used in conjunction with aluminum contacts. However, aluminum and silicon can participate in an intermetallic reaction. Consequently, silicon that contacts the aluminum may be absorbed into the aluminum layer providing a pathway for aluminum diffusion into the silicon substrate. Aluminum spikes can form that penetrate into the interior of the silicon. Upon intersection with underlying p/n junctions, the aluminum spikes can cause short circuits and disrupt device functionality.

To counteract aluminum spiking, a barrier layer may be formed on a silicon substrate to prevent the diffusion of aluminum from a metal layer into the substrate. The barrier layer may be titanium tungsten (TiW), for example. Possible benefits of TiW as a barrier layer are good electrical and thermal conductivity, strong adhesion to both silicon and aluminum, and processing compatibility. However, aluminum spiking may still occur with a TiW barrier layer.

According to various embodiments, the present invention discloses various methods of forming treated barrier layers on a substrate. The following description describes the various embodiments. FIGS. 1 and 2 illustrate embodiments for forming a treated barrier layer using thermal processing in the presence of a reactive material in a gaseous state. Embodiments for forming a treated barrier layer using multiple layers of barrier material and sealant material followed by thermal processing are illustrated in FIGS. 3-5. An alternative embodiment for forming a treated barrier layer using multiple layers of barrier material and sealant material without a thermal processing step is illustrated in FIG. 6. An embodiment for forming a semiconductor device with an treated barrier layer is illustrated in FIG. 7.

FIGS. 1A-1E illustrate a method of forming a treated barrier layer using thermal processing in accordance with an embodiment of the present invention.

FIG. 1A illustrates a cross-sectional view of a substrate after forming a recessed region in accordance with an embodiment of the present invention.

Referring to FIG. 1A, a recessed region is formed in a substrate 10 using suitable known methods. For the purposes of the present invention, the substrate 10 may be any material or combination of materials that includes a suitable surface on which material layers may be formed. In various embodiments, the substrate 10 may be a semiconductor substrate. In various embodiments, the substrate 10 may be a silicon substrate, germanium substrate or may be a compound semiconductor substrate including indium antimonide (InSb), indium arsenide (InAs), indium phosphide (InP), gallium nitride (GaN), gallium antimonide (GaSb), gallium arsenide (GaAs), silicon carbide (SiC), or combinations thereof. In one embodiment, the substrate 10 is a silicon substrate. In one or more embodiments, the substrate 10 comprises a stack such as GaN grown on silicon, GaN grown on silicon carbide, and others.

FIG. 1B illustrates a cross-sectional view of the substrate after forming a barrier layer over the surface of the substrate and the recessed region in accordance with an embodiment of the present invention.

Referring to FIG. 1B, a barrier layer 20 is formed over the surface of the substrate 10 and the recessed region. In some embodiments, the barrier layer 20 conforms to the sidewalls and bottom surface of the recessed region. In various embodiments, the barrier layer 20 includes multiple layers. The barrier layer 20 is a single layer in one embodiment. In various embodiments, the barrier layer 20 has a vertical thickness between 25 nm and 500 nm. In one embodiment, the barrier layer 20 has a vertical thickness of about 50 nm.

The barrier layer 20 may be formed using a deposition process. In various embodiments, the barrier layer 20 is formed using chemical vapor deposition (CVD), plasma enhanced CVD, chemical solution deposition, physical vapor deposition (PVD), atomic layer deposition (ALD), molecular beam epitaxy (MBE), plating, and, in one embodiment, is formed using sputter deposition.

In various embodiments, the barrier layer 20 is a refractory metal, a mixture of materials, or an alloy such as nichrome. In one embodiment, the refractory metal comprises molybdenum (Mo), tantalum (Ta), or tungsten (W). In one embodiment, the refractory metal may comprise titanium (Ti), vanadium (V), chromium (Cr), zirconium (Zr), or hafnium (Hf). In various embodiments, the barrier layer 20 comprises a conductive ceramic such as titanium nitride (TiN), tantalum nitride (TaN), tungsten nitride (WN₂), indium oxide (In₂O₃), and copper silicide (Cu₅Si) as examples. In one embodiment, the barrier layer 20 is titanium tungsten (TiW). In another embodiment, an additional layer comprising platinum silicide (PtSi) is included between the substrate 10 and the barrier layer 20 and the barrier layer 20 may be TiW.

FIG. 1C illustrates a cross-sectional view of the substrate during formation of a treated barrier layer using a thermal processing step in the presence of a reactive material in accordance with embodiments of the present invention.

Referring to FIG. 1C, the substrate 10 and the barrier layer 20 of FIG. 1B are subjected to a thermal processing step in the presence of a reactive material 30 after a vacuum break. The thermal processing step facilitates a process by which molecules of the reactive material 30 are inserted into the barrier layer. The combination of the barrier layer and the reactive material 30 form a treated barrier layer 23.

In one embodiment, the reactive material 30 is in a gaseous state during the thermal processing step as shown. Alternatively, the reactive material 30 may be present in a liquid state, a solid state, a plasma state, or any mixture thereof. In various embodiments, the reactive material 30 may comprise one or more of oxygen (O₂), water vapor (H₂O), carbon dioxide (CO₂), diborane (B₂H₄), nitrogen fluoride (NF₃), and silane (SiH₄) and is nitrogen (N₂) in one embodiment and is ammonia (NH₃), nitric acid and other acids having nitrogen, oxides of nitrogen, and other sources of nitrogen radicals in another embodiment.

The thermal processing step is a rapid thermal processing (RTP) step in one embodiment. In various embodiments, the RTP step increases the temperature to between 500° C. and 1000° C. during a time period between 10 s and 180 s. In one embodiment, the temperature is increased to about 750° C. during a time period of about 20 s.

The RTP step may be an isothermal process using broad area optical illumination to heat the barrier layer, an adiabatic process using excimer laser pulses to heat the barrier layer, or a thermal flux process where a focused electron beam or a laser beam is scanned across the barrier layer, as examples. In one embodiment, the RTP step is an isothermal process where an array of lamps emit electromagnetic radiation and heat transfer to the barrier layer is primarily radiative.

In some embodiments, the thermal processing step includes multiple short RTP steps. Each short RTP step may have distinct processing parameters including maximum temperature, temperature ramp rate, processing time, and type of reactive material 30. In various embodiments, complex barrier regions may be formed by repeating the processing steps in FIGS. 1B and 1C using similar or different materials for additional barrier layers and reactive materials.

The diffusion rate of the reactive material 30 into the barrier layer 20 is increased by the change in temperature during the thermal processing step. This may enhance the quality of the treated barrier layer 23 by increasing the density of the barrier layer. Additionally, the reactive material 30 may be chosen to form compounds with the barrier layer in the presence of heat. The compounds formed may be inert to the substrate 10 and to subsequently formed layers and further prohibit diffusion into the treated barrier layer 23. In various embodiments, the processing parameters of the thermal processing step may be chosen such that the reactive material 30 diffuses through the entire volume, a partial volume, or just a small region at the surface of the barrier layer.

If the thermal processing step in the presence of a reactive material 30 is omitted, grain boundaries in the barrier layer may provide a path for inter-diffusion of species between layers. The method illustrated in FIG. 1C overcomes this deficiency by forming a treated barrier layer 23 from the barrier layer 20 of FIG. 1B and a reactive material 30.

As an example, in FIGS. 1B and 1C, the substrate 10 may be silicon (Si), the barrier layer 20 may be titanium tungsten (TiW), and the reactive material 30 may be nitrogen (from NH₃ or N₂, as examples). The thermal processing step may be a rapid thermal processing (RTP) step in this example. The elevated temperature of the RTP step may cause nitrogen atoms to diffuse into the TiW forming a treated barrier layer 23. The thermal energy supplied by the RTP step may facilitate the formation of nitrides such as titanium nitride (TiN) and tungsten nitride (WN₂) in the treated barrier layer 23. The formation of nitrides in the treated barrier layer 23 may fill in and remove or significantly decrease in number the various pathways for diffusion of species such as titanium into and out of the treated barrier layer 23 while maintaining the desirable properties of TiW. Additionally, the thermal processing step may increase the robustness and lifetime of the treated barrier layer 23 compared to the barrier layer 20.

In an alternative embodiment, instead of annealing in a nitrogen atmosphere, a plasma nitridation process may be used. During a plasma nitridation process, the barrier layer 20 is subjected to a nitrogen plasma. The nitrogen radicals in the plasma may react with the barrier layer 20 to form a treated barrier layer 23. Additionally, the plasma nitridation may be performed at a lower temperature, for example, at 100° C. to 400° C., than needed for thermal nitridation.

FIG. 1D illustrates a cross-sectional view of the substrate after forming a material layer over the treated barrier layer comprising the reactive material in accordance with an embodiment of the present invention.

Referring to FIG. 1D, a material layer 40 is formed over the treated barrier layer 23 comprising the reactive material. The material layer 40 may be any material suitable for the specific design requirements of the structure. In various embodiments, the material layer 40 is a metal layer. The material layer 40 may comprise one or more of aluminium (Al), copper (Cu), silver (Ag), gold (Au), palladium (Pd), platinum (Pt), tungsten (W), and others. In various embodiments, the material layer 40 may include additives such as silicon (Si), nickel (Ni), tin (Sn), vanadium (V), hafnium (Hf), lead (Pb), and others. In various embodiments, the material layer 40 has a tensile stress.

In some embodiments, the material layer 40 may be an alloy comprising aluminum, silicon, and copper (AlSiCu). In various embodiments, the AlSiCu material layer may comprise between about 0.5% and 1.5% silicon and between about 0.25% and 0.75% copper. In one embodiment, the AlSiCu material layer is 98.5% aluminum, 1% silicon, and 0.5% copper.

Similar to the barrier layer 20, the material layer 40 may include multiple layers in some embodiments. In other embodiments, the material layer 40 is a single layer. The material layer 40 may be formed using a deposition process. In various embodiments, the material layer 40 is formed using a chemical vapor deposition (CVD), plasma enhanced CVD, chemical solution deposition, physical vapor deposition, atomic layer deposition (ALD), molecular beam epitaxy MBE, plating, and, in one embodiment, is formed using sputter deposition.

Referring to the previous example in which the substrate 10 is silicon, the barrier layer 20 is titanium tungsten (TiW), and the reactive material 30 is nitrogen (from NH₃ or N₂, as examples), a primarily aluminum (Al) metallization layer further comprising silicon (Si) and copper (Cu) may be chosen as the material layer 40. The addition of silicon and copper into the material layer 40 forms an AlSiCu alloy, which has enhanced properties relative to a pure aluminium layer. The silicon may be included to inhibit the reaction rate of aluminum from the material layer 40 with silicon from the substrate 10. The copper may be included to reduce electromigration caused by high voltages in thin interconnection lines.

TiW has desirable thermal and electrical properties and strong adhesion to the silicon in the substrate 10 and AlSiCu in the material layer 40. However, TiW commonly exists in a metastable phase and may be fine-grained or nanocrystalline. As a result, if the thermal processing step illustrated in FIG. 1C is omitted, titanium may continuously diffuse out of the barrier layer and react with the AlSiCu in the material layer 40. Intermetallic phase regions may form at the junction of the substrate and the barrier layer and the junction of the barrier layer and the metal layer due to the out-diffusion of titanium from the TiW layer and the aluminium from the AlSiCu layer.

Thermal processing of the barrier layer 20 in the presence of the nitrogen-based reactive material 30 forms a treated barrier layer 23 and serves to prevent any subsequent interaction of barrier layer 20 with subsequently formed layers such as an AlSiCu layer. In various embodiments, the reactive material 30 may form a surface layers, e.g., couple of mono-layers especially if the effective diffusivity of the reactive material 30 in the barrier layer 20 is much less than the thickness of the barrier layer 20. Alternatively, the reactive material 30 may diffuse into the barrier layer 20 and have a uniform concentration within the barrier layer 20. Alternatively, the reactive material 30 may be incorporated primarily in the grain boundaries in some embodiments comprising polycrystalline barrier layer. The nitrides of titanium and tungsten (TiN, WN₂, for example) formed within the treated barrier layer 23 may be inert towards the AlSiCu of the subsequently formed material layer 40. This prevents or significantly limits the formation of mixed layers between the substrate 10, treated barrier layer 23, and the material layer 40 and enhances the barrier quality. Additionally, the reactive material (e.g., nitrogen atoms) may fill into the grain boundaries and crystal lattice and remove the various pathways for diffusion of titanium and aluminum between the treated barrier layer 23 and the material layer 40 while maintaining desirable properties of TiW.

Therefore, in this example, the inclusion of a thermal processing step in the presence of nitrogen forms a treated barrier layer 23 that does not lose titanium due to out-diffusion and does not allow the reaction of titanium with silicon in the material layer 40. Reactions of titanium with the silicon of the substrate 10 and the material layer 40 may cause aluminum spiking. Since these reactions are prevented by the treated barrier layer 23, there are no pathways for aluminum diffusion through the treated barrier layer 23 and aluminum spiking does not occur.

Many applications such as power applications require thick front and back contacts and a thin substrate. If the thermal processing step in the presence of a reactive material is omitted, the stress of the material layer on the substrate may be uncompensated. Design compromises including increasing the thickness of the substrate to prevent warping and reducing the thickness of front and/or back contacts to reduce stress on the substrate may be made. However, this may reduce the capabilities of the device as a power device.

Deposited metal layers may inherently have tensile stress. Since the metal layer may be thick to support higher currents while the substrate may be thin relative to the metal layer in power applications, the effects of the tensile stress from the metal layer on the substrate may be significant. The treated barrier layer 23 may have higher compressive stress which can counteract the tensile stress of a thick metal layer and prevent substrate warping. In the above example, the high intrinsic compressive stress of the titanium tungsten (TiW) and nitrides in the treated barrier layer 23 better counteracts the tensile stress of the alloy of aluminum, silicon, and copper (AlSiCu) in the material layer 40 compared to the TiW alone.

FIG. 1E illustrates a cross-sectional view of the substrate after removing portions of the material layer and the treated barrier layer using a wet etching process.

Referring to FIG. 1E, select regions of the material layer and the treated barrier layer are removed from the substrate using a wet etching process. A possible advantage afforded by using, for example, a treated titanium tungsten (TiW) barrier layer as opposed to using a titanium nitride (TiN) barrier layer is that the treated titanium tungsten barrier layer is compatible with wet etching processes. In contrast, a titanium nitride barrier layer may only be compatible with dry etching processes.

The beneficial properties described above as well as other benefits may be attained with any suitable combination of materials for the substrate 10, barrier layer 20, reactive material 30, and material layer 40. Accordingly, the present inventive method is not limited to the materials used in the previous example or the benefits attained therein.

A layer 39 may be formed over the material layer 40. The layer 39 may be a multi-layer metal stack designed for bonding. The layer 39 may be deposited before the patterning in one embodiment. In one embodiment, the layer 39 includes a palladium layer, which is deposited using an electro plating process or electroless plating process. For example, such stress optimization and control may reduce defects formed during subsequent palladium plating processes, which may be used for corrosion resistance as well as a diffusion barrier layer. The palladium plating defects may be induced from platinum from previously deposited platinum silicide nanoparticles due to an electrochemical effect. However, higher stress may control the chip bow, easing the processing after sawing.

Further processing may continue as in conventional semiconductor processing.

FIGS. 2A-2D illustrate a method of forming a treated barrier layer using thermal processing in accordance with an alternative embodiment of the present invention where FIG. 2A illustrates a cross-sectional view of a substrate, FIG. 2B illustrates a cross-sectional view of the substrate after forming a barrier layer over the surface of the substrate, FIG. 2C illustrates a cross-sectional view of the substrate during formation of a treated barrier layer using a thermal processing step in the presence of a reactive material, and FIG. 2D illustrates a cross-sectional view of the substrate after forming a material layer over the treated barrier layer.

Referring to FIG. 2A, a substrate 10 is suitably prepared for subsequent material layer formation similar to FIG. 1A except that no recessed region is formed in the substrate 10. In various embodiments, the substrate 10 is substantially smooth having very few defects and/or large protruding features. Alternatively, the substrate 10 may be substantially rough, but without deep recessed regions within the substrate 10.

Referring to FIG. 2B, a barrier layer 20 is formed over the substrate 10. In some embodiments, the barrier layer 20 is non-conformal which may allow access to techniques and materials that may not be viable for the substrate of FIG. 1A. For example, some barrier materials may not conform to a substrate with large topographical variation and as a result may not make solid ohmic contact or adhere to the substrate. However, these same materials may be used as the barrier layer 20 if the substrate 10 is substantially smooth as shown in FIG. 2A. In other embodiments, a barrier material similar to those described in FIG. 1B is used and the barrier layer 20 functions as in FIG. 1B.

Referring to FIG. 2C, a treated barrier layer 23 is formed using thermal processing in the presence of a reactive material 30 as previously described in reference to FIG. 1C. In FIG. 2D, a material layer 40 is formed over the treated barrier layer 23 and the substrate 10. In some embodiments, the lack of a recessed region in the substrate 10 may also allow the use of other techniques and materials for the material layer 40 that would not otherwise be viable due to various design requirements similar to the barrier layer 20 described in FIG. 2B.

In the embodiments of FIGS. 1 and 2, a reactive material is present during the thermal processing step. The following embodiments described in FIGS. 3-5 describe alternative methods of forming a barrier layer using multiple layers of barrier material and a sealant material. In these embodiments, the sealant material reacts with the barrier material during the thermal processing step to form and treated barrier layer.

FIGS. 3A-3C illustrate a method of forming a barrier layer using thermal processing in accordance with another alternative embodiment of the present invention.

FIG. 3A illustrates a cross-sectional view of a substrate after forming a first barrier layer, a barrier modifier material source layer, and a second barrier layer over the surface of the substrate in accordance with embodiments of the present invention.

Referring to FIG. 3A, a first barrier layer 21 is formed over the surface of a substrate 10 such as those illustrated in FIGS. 1A and 2A. The first barrier layer 21 may be formed according to processes described previously in reference to FIG. 1B. Similarly, the first barrier layer 21 may be any suitable barrier material as previously described. The first barrier layer 21 may be chosen such that it has strong adhesion to the substrate 10. The first barrier layer 21 may also make good ohmic contact with the substrate and have desirable thermal and electrical properties. In one embodiment, the first barrier layer 21 is titanium tungsten (TiW).

In contrast to other embodiments, a barrier modifier material source layer 31 is formed over the first barrier layer 21. The barrier modifier material source layer 31 may serve to further enhance the barrier properties of the first barrier layer 21. In various embodiments, the barrier modifier material source layer 31 has different material properties than the first barrier layer 21. In various embodiments, the barrier modifier material source layer 31 may release the reactive material during subsequent annealing thereby forming the equivalent of the previously described treated barrier layer 23 (FIG. 1C). In one embodiment, the barrier modifier material source layer 31 comprises an amorphous material layer comprising nitrogen. In an alternative embodiment, the constituent material of the barrier modifier material source layer 31 may be chosen from those described previously in reference to the barrier layer of FIG. 1B. In one embodiment, the barrier modifier material source layer 31 is a titanium tungsten alloy that is infused with nitrogen during formation (TiWN). The TiWN barrier modifier material source layer may be formed using a deposition process such as sputter deposition, for example. The TiWN barrier modifier material source layer may be similar to the combination of the barrier layer and reactive material of FIG. 1C after thermal processing in that the TiWN is a mixture of nitrides such as titanium nitride (TiN) and tungsten nitride (WN₂) within the crystal structure of a TiW alloy. The TiWN may have higher compressive stress and enhanced barrier properties over other barrier layers.

A second barrier layer 22 is formed over the barrier modifier material source layer 31 and is materially identical to the first barrier layer 21 in some embodiments and different from the first barrier layer 22 in other embodiments. The second barrier layer 22 may be chosen such that it has strong adhesion to a subsequent layer. In one embodiment, the second barrier layer 22 is TiW. The second barrier layer 22 seals the barrier modifier material source layer 31 so that the reactive material does not escape out during the annealing.

FIG. 3B illustrates a cross-sectional view of the substrate after forming a mixed region using a thermal processing step in accordance with an embodiment of the present invention.

Referring to FIG. 3B, the substrate 10, first barrier layer 21, barrier modifier material source layer 31, and second barrier layer 22 are subjected to a thermal processing step. In comparison to the thermal processing step described in FIG. 1C where the thermal processing step was carried out in the presence of a reactive material, the thermal processing step in this embodiment may be carried out in a vacuum, inert atmosphere, or any other suitable nonreactive medium. Conversely, in other embodiments, a reactive material may be present during the thermal processing step to further enhance the barrier quality of the first barrier layer 21, barrier modifier material source layer 31, and second barrier layer 22.

The thermal processing step facilitates the mixing of materials between the first barrier layer 21, the barrier modifier material source layer 31, and the second barrier layer creating a mixed region 32.

In one embodiment, the thermal processing step is a rapid thermal processing step (RTP). In various embodiments, the RTP step increases the temperatures of the first barrier layer 21, the barrier modifier material source layer 31, and the second barrier layer 22 to between 500° C. and 1000° C. during a time period between 10 s and 30 s. In one embodiment, the temperatures of the first barrier layer 21, the barrier modifier material source layer 31, and the second barrier layer 22 are increased to about 750° C. during a time period of about 20 s.

FIG. 3C illustrates a cross-sectional view of the substrate after forming a material layer over the second barrier layer in accordance with an embodiment of the present invention.

Referring to FIG. 3C, a material layer 40 is formed over the second barrier layer 22, the mixed region 32, and the first barrier layer 21. The material layer 40 may comprise materials such as those described in reference to FIG. 1D.

FIGS. 4A-4C and 5A-5C illustrate methods of forming a barrier layer using thermal processing in accordance with alternative embodiments of the present invention, where FIG. 4A illustrates a cross-sectional view of a substrate after forming a barrier modifier material source layer and then a barrier layer over the surface of a substrate and FIG. 5A illustrates a cross-sectional view of a substrate after forming a barrier layer and then a barrier modifier material source layer over the surface of a substrate, FIGS. 4B and 5B illustrate cross-sectional views of the respective substrates after forming a mixed region using a thermal processing step, and FIGS. 4C and 5C illustrate cross-sectional views of the respective substrates after forming a material layer over the barrier layer.

Referring to FIG. 4A, a barrier modifier material source layer 31 is formed over a suitable substrate 10. A barrier layer 20 is subsequently formed over the barrier modifier material source layer 31. The barrier modifier material source layer 31 and the barrier layer 20 are as previously described. In one embodiment, the barrier modifier material source layer 31 is a nitrogen infused titanium tungsten alloy (TiWN) and the barrier layer 20 is titanium tungsten (TiW). In this embodiment, the sealant material 31 may be chosen to have strong adhesion to the substrate 10.

Referring to FIG. 5A, a barrier layer 20 is formed over the substrate 10. A barrier modifier material source layer 31 is subsequently formed over the barrier layer 20. The barrier layer 20 and barrier modifier material source layer 30 are as previously described. Accordingly, in one embodiment, the barrier layer 20 is TiW. In one embodiment, the barrier modifier material source layer is TiWN.

Referring to FIGS. 4B and 5B, the substrates 10, barrier layers 20, and barrier modifier material source layers 31 are subjected to a thermal processing step as previously described forming a mixed region 32 between the barrier layers 20 and the barrier modifier material source layers 31.

Referring to FIGS. 4C and 5C, a material layer 40 is formed over the barrier layer 20 and mixed region 32 as previously described.

The methods illustrated in FIGS. 3A-3C, 4A-4C, and 5A-5C are examples of different combinations of barrier layers 20 and barrier modifier material source layers 31. The substrate 10, barrier layer 20, first barrier layer 21, barrier modifier material source layer 31, second barrier layer 22, and material layer 40 may each comprise multiple layers and multiple materials. Additionally, as is apparent to a person of skill in the art, other combinations of layers may be used to achieve at least similar benefits to those attained by the invention as described.

FIGS. 6A-6C illustrate a method of forming a barrier layer in accordance with an embodiment of the present invention, where FIG. 6A illustrates a cross-sectional view of a substrate after forming a first barrier layer, a barrier modifier material source layer, a second barrier layer, and a material layer over the surface of the substrate, FIG. 6B illustrates a cross-sectional view of the substrate after forming a barrier modifier material source layer, a barrier layer, and a material layer over the surface of the substrate, and FIG. 6C illustrates a cross-sectional view of the substrate after forming a barrier layer, a barrier modifier material source layer, and a material layer over the surface of the substrate.

Referring to FIGS. 6A-6C, a material layer 40 is formed over the respective substrates, barrier layers, and barrier modifier material source layers as illustrated in accordance with previously described methods. In one embodiment, the barrier modifier material source layer 31 may be formed using the embodiment of FIGS. 1A-1D. Alternatively, the barrier modifier material source layer 31 may be deposited and release the reactive material during subsequent processing, for example, as described in FIG. 3A-3C.

FIGS. 7A-7G illustrate a method of forming a semiconductor device comprising a treated barrier layer in accordance with an embodiment of the present invention.

According to the embodiments of the present invention, the semiconductor device may include active devices as well as passive devices. The semiconductor device may be a power semiconductor device. Examples of power semiconductor devices include discrete PN diodes, Schottky diodes, junction gate field-effect transistors (JFETs), metal-oxide-semiconductor field-effect transistors (MOSFETs), bipolar junction transistors (BJTs), insulated-gate bipolar transistors (IGBTs), depletion enhancement MOSFETs, lateral double-diffused MOSFETs (LDMOSFETs), and others. The power semiconductor device may be a wide-bandgap semiconductor device such as a silicon carbide device and a gallium nitride device.

FIG. 7A illustrates a cross-sectional view of a substrate after forming a deep well region in the substrate and forming a well region within the deep well region in accordance with an embodiment of the present invention.

Referring to FIG. 7A, the semiconductor device includes a substrate 10. In various embodiments the substrate 10 may be a semiconductor substrate. In various embodiments, the substrate 10 may be a silicon substrate, germanium substrate or may be a compound semiconductor substrate including indium antimonide (InSb), indium arsenide (InAs), indium phosphide (InP), gallium nitride (GaN), gallium antimonide (GaSb), gallium arsenide (GaAs), silicon carbide (SiC), or combinations thereof. In one embodiment, the substrate 10 is a silicon substrate. In one or more embodiments, the substrate 10 comprises a stack such as GaN grown on silicon, GaN grown on silicon carbide, and others. In one embodiment, the substrate 10 is a silicon wafer that is formed with an initial doping type. In an alternative embodiment, the substrate 10 is a silicon wafer that is doped using diffusion. For example, a doped layer is deposited over an undoped substrate and the substrate annealed so as to diffuse the dopants from the doped layer into the undoped substrate.

Referring still to FIG. 7A, a deep well region 50 is formed in the substrate 10. A doped region 51 is formed in the deep well region 50. The deep well region 50 and doped region 51 may be formed using an ion implantation process, a diffusive process, and others. The doped region 51 may be formed by counter doping the deep well region 50. In one embodiment, the deep well region 50 has an opposite doping type as the substrate 10. In one embodiment, the doped region 51 has an opposite doping type as the deep well region 50 and the same doping type as the substrate 10.

FIG. 7B illustrates a cross-sectional view of the substrate after forming a gate dielectric, forming a gate material over the gate dielectric, and forming an insulating region over the gate material in accordance with an embodiment of the present invention.

Referring to FIG. 7B, a gate dielectric 52 is formed over the substrate 10, the deep well region 50, and the doped region 51. The gate dielectric 52 may be grown or deposited, for example, on the surface of the substrate 10, deep well region 50, and doped region 51. Deposition methods of the gate dielectric 52 may include chemical vapor deposition (CVD), physical vapor deposition (PVD), molecular beam epitaxy (MBE), and atomic layer deposition (ALD). In one embodiment, the substrate 10 is silicon and the gate dielectric 52 is silicon dioxide (SiO₂) that is formed by exposing the surface of the silicon to oxygen (O₂).

Still referring to FIG. 7B, a gate material 53 is formed over the gate dielectric 52. The gate material 53 may be formed using a physical vapor deposition (PVD) method such as electron beam evaporation or sputter deposition, for example. In various embodiments, the gate material 53 is an electrically conducting material. In one embodiment, the gate material 53 is polysilicon. In another embodiment, the gate material 53 is a metal. In various embodiments, the gate material 53 includes a silicide.

An insulating region 54 is formed over the gate material 53 and the gate dielectric 52. The insulating region 54 may be formed using a deposition method including chemical vapor deposition (CVD), physical vapor deposition (PVD), molecular beam epitaxy (MBE), and atomic layer deposition (ALD). In various embodiments, the insulating region 54 has the same material composition as the gate dielectric 52. In other embodiments, the insulating region 54 is an insulating material that is different than the gate dielectric 52.

FIG. 7C illustrates a cross-sectional view of the substrate after forming a recessed region in the insulating region, well region, and deep well region in accordance with an embodiment of the present invention.

Referring to FIG. 7C, a recessed region is formed in the deep well region 50, doped region 51, and insulating region 54. The recessed region may be formed using an etching technique such as reactive ion etching (RIE). The recessed region may be used to provide access for subsequent layers to make electrical contact with the deep well region 50 and the doped region 51. In this particular example, the deep well region 50 and the doped region 51 will be shorted and coupled through the electrical contact that is being formed.

FIG. 7D illustrates a cross-sectional view of the substrate after forming a barrier layer over the recessed region and the insulating region in accordance with an embodiment of the present invention.

Referring to FIG. 7D, a barrier layer 20 is formed over the recessed region and the insulating region 54 as previously described. The barrier layer 20 may prevent diffusion between the deep well region 50 and subsequent layers and between the doped region 51 and subsequent layers. The material of the barrier layer 20 may be chosen such that the barrier layer 20 adheres to the deep well region 50, doped region 51 and the insulating region 54. In various embodiments, the barrier layer 20 includes a refractory metal or refractory metal nitride, metal alloy, or a conductive ceramic and is titanium tungsten (TiW) in one embodiment. In one embodiment, the refractory metal or refractory metal nitride comprises molybdenum (Mo), tantalum (Ta), or tungsten (W). In one embodiment, the refractory metal or refractory metal nitride may comprise titanium (Ti), vanadium (V), chromium (Cr), zirconium (Zr), or hafnium (Hf).

FIG. 7E illustrates a cross-sectional view of the substrate during formation of a treated barrier layer using a thermal processing step in the presence of a reactive material in accordance with an embodiment of the present invention.

Referring to FIG. 7E, a treated barrier layer 23 is formed using a thermal processing step in the presence of a reactive material 30. The barrier layer 20 illustrated in FIG. 7D may include various pathways for diffusion. The thermal processing step may facilitate diffusion of a reactive material 30 into of the barrier layer 20. Increased thermal energy at the barrier layer 20 may increase diffusion rates of the reactive material 30 into the barrier layer 20 forming a treated barrier layer 23. Further the increased thermal energy may provide all or some of the required energy to form various compounds within the treated barrier layer 23 comprising the elements of the barrier layer 20 and elements of the reactive material 30.

The diffusion of the reactive material 30 into the barrier layer 20 may enhance the quality of the treated barrier layer 23, e.g., by increasing the density of the barrier layer 20. The phases formed between the elements of the barrier layer 20 and the reactive material 30 may be inert to the substrate 10 and to subsequently formed layers and further prohibit diffusion into the treated barrier layer 23. In various embodiments, the processing parameters of the thermal processing step may be chosen such that the reactive material 30 diffuses through the entire volume, a partial volume, or just a small region at the surface of the barrier layer.

The thermal processing step may take place in a furnace or an oven. The thermal processing step may be a single wafer or multi-wafer process. In various embodiments, the thermal processing step is a rapid thermal processing (RTP) step during which the temperature is increased over a short time period (on the order of seconds). In other embodiments, the RTP step increases the temperature over a time period on the order of milliseconds. The RTP step may be an isothermal process using broad area optical illumination, an adiabatic process using excimer laser pulses, or a thermal flux process where a focused electron beam or a laser beam is scanned across a surface. In various embodiments, the RTP step uses a high intensity heat lamp to rapidly increase the temperature at the surface. In various embodiments, the RTP step increases the temperature to between 500° C. and 1000° C. during a time period between 10 s and 30 s. In one embodiment, the temperature is increased to about 750° C. during a time period of about 20 s. In some embodiments, wafers may be rotated during the RTP step to further facilitate even heating.

On possible benefit of using a rapid thermal processing (RTP) step is to limit the necessary time that the wafer is at a high temperature. The increase of the diffusion rate of the reactive material 30 into the barrier layer 20 is beneficial for penetrating the barrier layer 20 during the RTP step. However, increased diffusion rates may occur in other areas of the substrate if the wafer is held at an elevated temperature for too long. The RTP step may increase the temperature at the surface of the barrier layer 20 in a sufficiently short amount of time so as to prevent other undesirable effects of high temperature in other areas of the wafer.

In some embodiments, the thermal processing step includes multiple short RTP steps. Each short RTP step may have distinct processing parameters including maximum temperature, temperature ramp rate, processing time, and type of reactive material 30. In various embodiments, complex barrier regions may be formed by repeating the processing steps in FIGS. 7D and 7E using similar or different materials for additional barrier layers and reactive materials.

In one embodiment, the reactive material 30 is in a gaseous state during the thermal processing step as shown. Alternatively, the reactive material 30 may be present in a liquid state, a solid state, a plasma state, or any mixture thereof. In various embodiments, the reactive material 30 may comprise nitrogen sources or carbon sources such as carbon dioxide (CO₂), and is nitrogen (N₂) in one embodiment, or ammonia (NH₃) in another embodiment.

The structure of the treated barrier layer 23 may be influenced by the amount of reactive material 30 available at the surface of the treated barrier layer 23. For example, if the reactive material 30 is supplied by a material in a gaseous state, the pressure, flow rate, and direction of flow of the gas may influence the structure of the treated barrier layer 23. The diffusion rate and reaction rate of the reactive material 30 in the treated barrier layer 23 may be increased by increasing the pressure of the gas. Consequently, the gas pressure may be controlled during the thermal processing step. In one or more embodiments, the pressure of the gas supplying the reactive material 30 is between 0.1 bar and 10 bar. In one embodiment, the pressure of the gas supplying the reactive material 30 is about 1 bar.

The diffusion rate and reaction rate of the reactive material 30 with the barrier layer 20 may also be increased by increasing the flow rate of the gas supplying the reactive material 30 and making the direction of flow perpendicular to the surface of the barrier layer 20.

Similar to the examples described in reference to FIGS. 1B and 1C, the substrate 10 may be silicon (Si), the barrier layer 20 may be titanium tungsten (TiW), and the reactive material 30 may be nitrogen (from NH₃ or N₂, as examples). The thermal processing step may be a rapid thermal processing (RTP) step in this example. The elevated temperature of the RTP step may cause nitrogen atoms to diffuse into the TiW forming a treated barrier layer 23. The thermal energy supplied by the RTP step may facilitate the formation of nitrides such as titanium nitride and tungsten nitride (e.g., WN₂) in the treated barrier layer 23. The formation of nitrides in the treated barrier layer 23 may fill in and remove or significantly decrease in number the various pathways for diffusion while maintaining the desirable properties of TiW.

Advantageously, by incorporating a reactive material into a barrier layer using a thermal process, no additional patterning/masking step is needed. As in the example above, a thermal processing step incorporating nitrogen as the reactive material into a titanium tungsten (TiW) barrier layer forms nitrides such as titanium nitride (TiN) locally within the barrier layer. If a titanium nitride (TiN) barrier layer is deposited instead of using a thermal process and a TiW barrier layer, the TiN barrier layer would have to be structured to avoid shorting, which requires an additional masking step.

FIG. 7F illustrates a cross-sectional view of the substrate after forming a top contact over the treated barrier layer in accordance with an embodiment of the present invention.

Referring to FIG. 7F, a material layer that is a top contact 41 of the semiconductor device is formed over the treated barrier layer 23 as previously described. The top contact 41 may provide electrical contact and/or thermal contact to the deep well region 50 and the doped region 51. The material of the top contact 41 may be electrically conductive and/or thermally conductive. In various embodiments, the top contact 41 is a metal or an alloy and is an alloy of aluminum, silicon, and copper (AlSiCu) in one embodiment. In various embodiments, the AlSiCu top contact may comprise between about 0.5% and 1.5% silicon and between about 0.25% and 0.75% copper. In one embodiment, the AlSiCu top contact is 98.5% aluminum, 1% silicon, and 0.5% copper.

Optionally, an implantation region 55 is formed in the substrate 10 on the backside of the semiconductor device. The implantation region 55 may be formed using ion implantation methods. In various embodiments, the implantation region 55 is doped. In one embodiment, the implantation region 55 has the opposite doping type as the substrate 10 and the semiconductor device is an insulated-gate bipolar transistor (IGBT) device. In an alternative embodiment, the implantation region 55 has the same doping type as the substrate 10 and the semiconductor device is a planar metal-oxide-semiconductor field-effect transistor (MOSFET) device. The IGBT device and the planar MOSFET device may be power semiconductor devices.

In one embodiment, the gate material 53 is coupled to a gate connection 701, the top contact 41 is coupled to an emitter connection 702, and the implantation region 55 is coupled to a collector connection of the semiconductor device and the semiconductor device is an IGBT. In an alternative embodiment, the gate material 53, top contact 41, and implantation region 55 are coupled to a gate connection 701, source connection, and drain connection of the semiconductor device respectively and the semiconductor device is a planar MOSFET device.

FIG. 7G illustrates a cross-sectional view of the substrate after adding a backside treated barrier layer and a backside contact in accordance with an embodiment of the present invention.

Referring to FIG. 7G, an optional backside treated barrier layer 24 may be formed over the implantation region 55 or the substrate 10 if the implantation region 55 is omitted. The backside treated barrier layer 24 may be formed as previously described in reference to the treated barrier layer 23. A material layer that is a backside contact 42 is formed over the backside treated barrier layer 24. The backside contact 42 may provide electrical and/or thermal contact to the implantation region 55 and the substrate 10. In various embodiments, the backside contact 42 is a metal or an alloy and is an alloy of aluminum, silicon, and copper (AlSiCu) in one embodiment.

In the case that the semiconductor device is an IGBT device, the backside contact 42 is a collector connection 703. In the case that the semiconductor device is a planar MOSFET device, the backside contact 42 is a drain connection.

Accordingly, as described above in various embodiments of the present invention, barrier layers reduce and/or eliminate the detrimental effects of inter-diffusion while also providing good electrical contact (low electrical contact resistance and good adhesion).

Other semiconductor devices using treated barrier layers are also possible. For example, a diode fabricated on a silicon substrate with a platinum silicide (PtSi) Schottky contact and an aluminum silicon copper (AlSiCu) top contact. A titanium tungsten (TiW) barrier layer that has been doped/nitrided with nitrogen is introduced between the substrate and the top contact using the previously described methods. Use of such a treated barrier layer may help to reduce defects, which would be introduced otherwise.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. As an illustration, the embodiments described in FIGS. 1-7 may be combined with each other in alternative embodiments. It is therefore intended that the appended claims encompass any such modifications or embodiments.

1. A method of fabricating a semiconductor device, the method comprising:
forming a barrier layer over a surface of a semiconductor substrate;
forming a treated barrier layer by subjecting an exposed surface of the barrier layer to a surface treatment process, wherein the surface treatment process comprises treating the surface with a reactive material; and
forming a material layer over the treated barrier layer, wherein the material layer comprises a metal.

2. The method of claim 1, wherein treating the surface with the reactive material comprises depositing a material layer comprising the reactive material.

3. The method of claim 1, wherein the method further comprises:
forming a recessed region in the semiconductor substrate before forming the barrier layer over the surface of the semiconductor substrate, wherein the barrier layer is a conformal barrier layer.

4. The method of claim 1, wherein a vertical thickness of the barrier layer is between 25 nm and 500 nm.

5. The method of claim 1, wherein the barrier layer comprises a refractory metal.

6. The method of claim 1, wherein the semiconductor substrate comprises silicon, the barrier layer comprises titanium tungsten, the reactive material comprises nitrogen, boron, or carbon, and the material layer comprises an alloy comprising aluminum, silicon, and copper.

7. The method of claim 6, wherein the reactive material comprises nitrogen gas (N2).

8. The method of claim 6, wherein the reactive material comprises ammonia (NH4).

9. The method of claim 6, wherein the treated barrier layer comprises titanium nitride and tungsten nitride.

10. The method of claim 1, wherein the surface treatment process is performed for a time period between 10 s to 180 s, and at a temperature between 500° C. to 1000° C.

11. The method of claim 1, further comprising patterning the treated barrier layer using a wet etching process.

12. A method of fabricating a semiconductor device, the method comprising:
forming a trench in a semiconductor substrate;
forming a titanium tungsten layer over a major surface of the semiconductor substrate and the trench;
forming a treated titanium tungsten layer by exposing the titanium tungsten layer to a reactive element comprising nitrogen, boron, or carbon; and
depositing an alloy layer comprising aluminum, silicon, and copper, the alloy layer contacting the treated titanium tungsten layer.

13. The method of claim 12, wherein forming the treated titanium tungsten layer by the exposing comprises:
annealing in a furnace comprising the reactive element.

14. The method of claim 13, wherein an atmosphere in the furnace during the annealing comprises ammonia or molecular nitrogen.

15. A method of fabricating a semiconductor device, the method comprising:
forming a metal silicide at a major surface of a semiconductor substrate;
forming a first conductive layer having a compressive stress over the metal silicide, the first conductive layer comprising a first metal, a second metal, and a reactive element that comprises nitrogen, boron, or carbon; and
depositing a second conductive layer having a tensile stress, the second conductive layer contacting the first conductive layer.

16. The method of claim 15, wherein the first metal comprises titanium and the second metal comprises tungsten, and wherein the second conductive layer comprises aluminum, silicon, and copper.

17. The method of claim 15, wherein the metal silicide comprises platinum silicide.

18. The method of claim 15, further comprising palladium plating the second conductive layer.

19-29. (canceled)
